(19) United States
(12) Patent Application Publication
(10) Pub. No.: US 2008/0260499 A1
(43) Pub. Date: Oct. 23, 2008

(54) FACET ADAPTER FOR A WAFER HANDLER

(76) Inventor: Peter van der Meulen, Newburyport, MA (US)

Correspondence Address: STRATEGIC PATENTS P.C.., C/O PORTFOLIOIP, P.O. BOX 52050, MINNEAPOLIS, MN, 55402, US

(21) Appl. No.: 12/104,193

(22) Filed: Apr. 16, 2008

Related U.S. Application Data
(60) Provisional application No. 60/912,137, filed on Apr. 16, 2007.

(51) Int. Cl. H01L 21/67

(52) U.S. Cl. 414/217; 901/40

(57) ABSTRACT

A facet adapter permits flexible coupling of wafer handler ports to various combinations of process modules. In one embodiment, a facet adapter connects a port of a wafer handler to two process modules. The facet adapter may provide additional facets oriented, for example, at ninety degrees to one another. Facet adapters may be employed to flexibly accommodate various semiconductor fabrication system layouts, and in particular, to increase the number of process modules serviced by a single robotic wafer handler.

### RELATED APPLICATIONS

This application claims the benefit of U.S. Prov. App. No. 60/912,137 filed on Apr. 16, 2007, incorporated by reference herein in its entirety.

### BACKGROUND

1. Field

This invention relates to facet adapters for us in interconnecting semiconductor manufacturing process modules.

2. Background

While numerous process modules are available for use in semiconductor manufacturing, these modules are typically built around a proprietary or company-specific platform. There remains a need for adapters that can flexibly connect various process modules to a vacuum handling system.

### SUMMARY OF THE INVENTION

A facet adapter permits flexible coupling of wafer handler ports to various combinations of process modules. In one embodiment, a facet adapter connects a port of a wafer handler to two process modules. The facet adapter may provide additional facets oriented, for example, at ninety degrees to one another. Facet adapters may be employed to flexibly accommodate various semiconductor fabrication system layouts, and in particular, to increase the number of process modules serviced by a single robotic wafer handler.

[additional summary to be based on claims as finalized.]

### BRIEF DESCRIPTION OF FIGURES

The foregoing and other objects and advantages of the invention will be appreciated more fully from the following further description thereof, with reference to the accompanying drawings wherein:

FIG. 1 shows a wafer handling system including a robotic handler that may be used with the systems and methods disclosed herein.

FIG. 2 shows a wafer handling system using a facet adapter.

FIG. 3 shows a layout for a wafer handling system using multiple facet adapters.

FIG. 4 shows a layout for a wafer handling system using multiple facet adapters.

### DETAILED DESCRIPTION

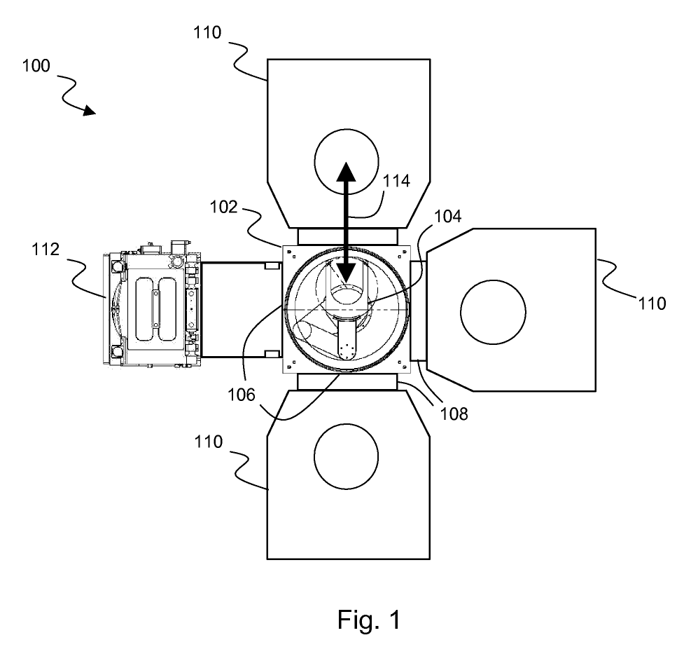

FIG. 1 shows a wafer handling system including a robotic handler that may be employed with the methods and systems disclosed herein. In one example layout, the wafer handling system 100 includes a wafer handler 102 having a robotic arm 104 and a plurality of ports 106, a plurality of isolation valves 108, a plurality of process modules 110 and the like, and a load lock 112. It will be understood that the following description is provided by way of example and not of limitation, and that numerous variations are possible to the basic layout described below.

In general, the wafer handler 102 (also referred to herein as a substrate handler) interconnects process modules 110 and the like in a vacuum environment, and provides a means, such as the robotic arm 104 described below, for moving wafers and the like among the various other interconnected components within the vacuum environment. Although not depicted, it will be understood that additional hardware (such as sensors, motors, valves, and so forth) and software (including device specific software implemented as application specific integrated circuits, firmware, ladder logic and the like, as well as system level and/or fabrication facility level software and so forth) may be employed to control operation of the wafer handler 102 and its various connected components to process wafers in a desired fashion. It will be further understood that, while the systems described herein may be usefully employed to handle and process semiconductor wafers, various other workpieces may be handled by the system including without limitation cleaning wafers, test wafers, and so forth. Still more generally, any substantially flat substrate, including a MicroElectroMechanical System (“MEMS”) substrate, a magnetic head disc, a CD, a CD ROM, a DVD, a photovoltaic substrate, a flat panel display device, a reticle, and the like, as well as various combinations of the foregoing, may be handled using the systems and methods described herein. All such workpieces and substrates are intended to fall within the scope of the term “wafer” as used herein, unless a different meaning is explicitly provided or otherwise clear from the context. Similarly, terms such as “substrate” and “workpiece” are intended to generally refer to any of the above unless a different meaning is explicitly provided or otherwise clear from the context. In various embodiments, all such wafers may be handled by the wafer handling system 100. It will be further understood that, while a substantially square, four-sided wafer handler 102 with four ports 106 is shown, that other shapes and configurations may be employed, such as a six-sided wafer handler 102 or an eight-sided wafer handler 102.

The wafer handling system 100 may employ a robotic arm 104 or the like to move wafers among the ports of the wafer handler 102. The robotic arm 104 may include an end effector or similar paddle or other device on an end thereof to pick and place wafers. In certain embodiments, a three-link or four-link Selective Compliant Assembly Robot Arm (“SCARA”) unit is employed to provide the reach and navigation through the handler and facet adapters, as shown, for example in the following figures. However, it will be understood that numerous other types of robotic arms and other wafer handlers exist that may be usefully adapted to the systems and methods described herein. By way of example and not of limitation, the system may employ dual SCARA arms, multi-link SCARA arms, articulated robots, Cartesian coordinate robots, telescoping robot arms, frog-leg arms, and so forth.

The wafer handler 102 may include a plurality of ports 106 (only two of the four ports in the square system 100 of FIG. 1 are numbered). The ports 106 may be constructed to industry-wide standards using, for example, SEMI standard specifications. While current fabrication systems are typically constructed for three-hundred millimeter wafers, it will be understood that smaller or larger wafers may be processed. Whether constructed according to industry standards or proprietary or other closed specifications, each port 106 will typically have an opening for passage of a wafer and an end effector or the like (such as any of the robotic arms 104 and end effectors described above). Each port 106 will also have a mounting surface—the surface where the port 106 of the wafer handler 102 physically couples to a corresponding surface of the process module 110, isolation valve 108, or other hardware. It will be understood that, while depicted simply as a plane in FIG. 1, the mounting surface of each port 106, and the corresponding mounting surfaces of hardware connected thereto, may include a variety of features such as gaskets, lips, grooves, through-holes, threaded holes, keying for mechanical registration, and so forth. All such variations consistent with vacuum-sealed engagement between the mounting surface of a port and any hardware coupled thereto may be suitably employed without departing from the scope of the systems and methods described herein. In general, the term “facet” as used herein is intended to refer to this mounting surface of any item of vacuum hardware described herein, which may include complementary facets designed to couple to one another, as well as non-complementary facets for which some form of adapter would typically be required in order to interconnect parts.

Isolation valves 108 may be employed to selectively isolate interior chambers of hardware (such as the process modules 110) connected to the wafer handler 102. The isolation valves 108 may include slit valves, slot valves, or any other hardware suitable for selective isolation of interior volumes of a vacuum handling system. In various embodiments, the isolation valves 108 may be integrated into the wafer handler 102, integrated into the process modules 110, or provided as separate hardware positioned between the wafer handler 102 and each process module 110 (or other hardware coupled to a port 106) where environmental isolation is desired. In this latter case, the isolation valve 108 is coupled in a vacuum-sealed engagement to the port 106 and the process module 110 respectively.

The process modules 110 may include any vacuum processing equipment including without limitation tools for epitaxy, chemical vapor deposition, physical vapor deposition, etching, plasma processing, lithography, plating, cleaning, spin coating, and so forth. In the following description, references to a tool or process module will be understood to refer to any tool or process module suitable for use in a semiconductor manufacturing process unless a different meaning is explicitly provided or otherwise clear from the context.

A load lock 112 provides a path for wafers into and out of the vacuum environment maintained by the wafer handling system 100. A variety of single wafer and multi-wafer load locks are known and may be suitably employed with the systems and methods described herein.

In general operation, a wafer is introduced into the vacuum environment of the wafer handling system 100 through the load lock 112, and transported among the process modules 110 with the robotic arm 104 (such as along draw path 114) according to a desired processing recipe. In various embodiments, a number of wafers may be concurrently processed within the wafer handling system 100. While the wafer handling system 100 described above readily accommodates up to three process modules 110 on the ports 106 of the wafer handling system 102, a particular process may call for four or more process modules 110. A facet adapter as described below may be advantageously employed to expand the number of process modules 110 attached to the system 100 without requiring additional wafer handling systems 102 or other transport mechanisms.

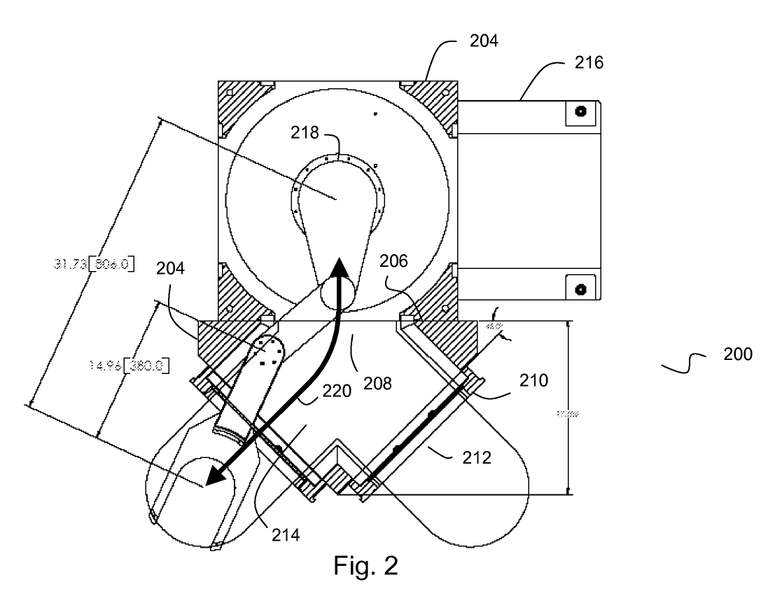

FIG. 2 shows a wafer handling system 200 using a facet adapter 202 to support two process modules at a single port of a wafer handler 204, which may be any of the wafer handlers described above with reference to FIG. 1. The facet adapter 202 includes a first facet 206 with an opening 208, a plurality of additional facets 210 with openings 212, and an interior 214. One or more connectors 216 may be optionally employed, connected to either one of the ports 208 of the wafer handler 204, or connected one of the additional facets 210 to accommodate various system layouts. In general, the wafer handling system 200 includes a robotic arm 218 that moves wafers along a draw path such as the path indicated by an arrow 220.

The first facet 206 is, in general, shaped and sized for removable and replaceable attachment in a vacuum-sealed engagement to a port of the wafer handler 204. This may include, for example, a complementary surface shape, along with any through-holes, threaded holes, and the like for mechanically affixing the facet adapter 202 to the wafer handler 204 with the port of the wafer handler 204 and the opening 208 of the first facet 206 adapter properly aligned for passage of a wafer and the robotic arm 218. The surface shape of the mounting surface of the first facet 206 may also include gaskets, or guides, grooves, or the like for gaskets, as well as mechanical registration features having corresponding, keyed features on the mounting surface of the port of the wafer handler 204. It will be understood that, while a removable and replaceable attachment such as bolts or other fasteners provides a modular assembly that can be reconfigured according to manufacturing needs, a more permanent assembly such as welding, epoxy, or the like may also be employed consistent with the use of a facet adapter as described herein.

The plurality of additional facets 210 (only one of which is numbered in FIG. 2) are, in general, shaped and sized for removable and replaceable attachment in a vacuum-sealed engagement to a process module (not shown). This may include, for example, a complementary surface shape, along with any through-holes, threaded holes, and the like for mechanically affixing one of the plurality of additional facets 210 of the facet adapter 202 to the process module with an entrance to the process module and the opening 212 of the additional facet 210 properly aligned for passage of a wafer and the robotic arm 218. The surface shape of the mounting surface of the additional facet 210 may also include gaskets, or guides, grooves, or the like for gaskets, as well as mechanical registration features having corresponding, keyed features on the mounting surface of the process module. It will be understood that, while a removable and replaceable attachment such as bolts or other fasteners provides a modular assembly that can be reconfigured according to manufacturing needs, a more permanent assembly such as welding, epoxy, or the like may also be employed consistent with the use of a facet adapter as described herein.

In one embodiment the additional facet 210 has a shape substantially consistent with the mounting surface of a port of the wafer handler 204 and substantially complementary to the surface shape of a process module, at least where the two surfaces mechanically mate to one another, so that a process module designed for attachment to the wafer handler 204 can instead be attached to the additional facet 210 of the facet adapter. Similarly, the surface shape of the first facet 206 has a shape substantially consistent with the mounting surface of the process module and substantially complementary to the surface shape of the port of the wafer handler 204, at least where the two surfaces mechanically mate to one another. In general, this permits use of the face adapter to add process modules to the wafer handler 204 without requiring redesign or modification of the physical interface between these components, or a deviation from industry standards for same. However, it certain embodiments, the facet adapter 202 may be used to couple non-complementary devices with suitable variations to the mounting surface of the first facet 206, the additional facet 210, or both.

It will be appreciated that substantially complementary shapes, as described herein, generally include shapes that three-dimensionally match one another so that they can be mechanically mated to one another along some portion of their respective surfaces. However, complementary shapes may also, or instead, refer to the shape and size of an opening along the surface of the respective surfaces, with complementary shapes including aligned openings for passage of a wafer or other substrate.

It will be noted that each one of the additional facets 210 presents a substantially planar surface tangent to the additional facet 210, excluding any of the various mechanical surface features noted above or the like. In one embodiment, the facet adapter 202 includes exactly two additional facets 210 with the planar surfaces thereof oriented at ninety degrees to one another (and at forty-five degrees to the first facet 206). In another embodiment, the facet adapter 202 includes exactly three additional facets 210 with the planar surfaces of adjacent facets oriented at ninety degrees to one another. It will be understood that a facet adapter 210 as described herein may include more openings, and may present additional facets at other, different relative orientations, without departing from the scope of this disclosure.

The interior 214 generally provides sufficient volume within the vacuum environment of the wafer handling system 200 to accommodate passage of a wafer and a robotic arm 218 or the like that handles the wafer. The specific dimensions of the interior may vary according to the type of robotic arm 218, the size of the wafer being handled, and any other appropriate criteria. It will also be understood that the interior 214 of the facet adapter 210 may include set-offs, shelves, or other hardware to hold substrates in transition between the wafer handler 204 and hardware (process modules, additional wafer handlers, and so forth) connected to any one of the additional facets 212. For example, in one embodiment, the interior 214 may include at least one shelf for holding a wafer. In one embodiment, multiple shelves may be used in combination with a robotic arm 218 having z-axis capability to buffer a number of wafers within the facet adapter 202, which may usefully accommodate variations to wafer paths through the system 200 and concurrent handling of multiple wafers within the system 200.

A connector 216 may be provided for more flexible layouts, such as to provide clearance for a particularly large or particularly wide process module, or to provide spacing between adjacent wafer handlers, each of which might use facet adapters such as those described above to rearrange or increase the number of process modules connected thereto. The connector 216 may include a first end, a second end, and an interior passage, with the first and second ends coupled in a vacuum-sealed engagement to various components of the system 200, such as a process module and the wafer handler 204. The interior may, in general, provide sufficient volume for passage by a wafer and ay handling hardware such as a robotic arm and end effector.

Although not shown in FIG. 2, it will be understood that an isolation valve or the like, such as any of the isolation valves described in reference to FIG. 1, may be employed at the first facet 206 (i.e., between the facet adapter 202 and the wafer handler 204) or at any one or more of the additional facets 210 (i.e., between one of the additional facets 210 and a process module).

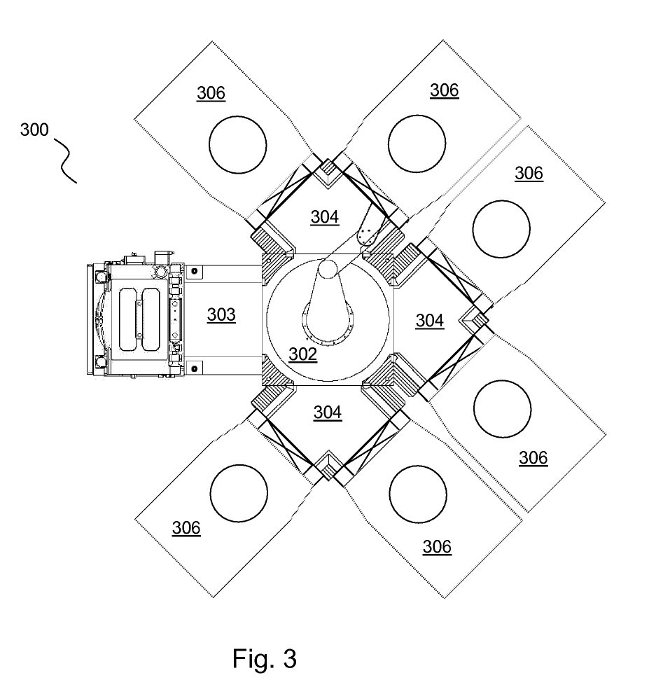

FIG. 3 shows a layout for a wafer handling system using multiple facet adapters. The system 300 generally includes a wafer handler 302, a load lock 303, a plurality of facet adapters 304, and a plurality of process modules 306, all of which may be as generally described above. More specifically, the system 300 depicted in FIG. 3 employs three facet adapters 304 to couple six process modules 306 to three ports of the wafer handler 302. The load lock 303 provides for movement of wafers between the interior vacuum environment of the system 300 and atmosphere (or some other controlled, vacuum, or non-vacuum environment).

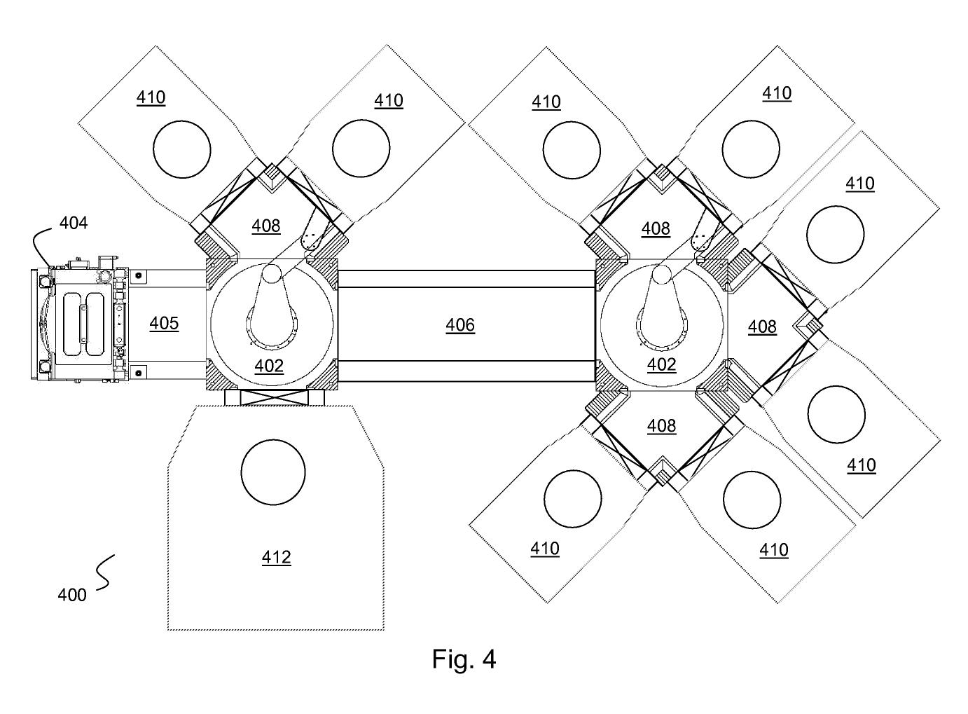

FIG. 4 shows a layout for a wafer handling system using multiple facet adapters. The system 400 generally includes a plurality of wafer handlers 402, a load lock 404 (which may be coupled to a process module 412 with a short connector 405 or the like), a connector 406, a plurality of facet adapters 408, a plurality of process modules 410, and a large process module 412, all of which may be as generally described above. More specifically, the system 400 employs four facet adapters 408 to accommodate eight process modules 410 at four ports of two different wafer handlers 402, leaving four additional wafer handler ports to connect to the connector 406, the load lock 404, and the large process module 412, which has too large a footprint to sit immediately adjacent to any of the other smaller process modules 410 attached to the facet adapters 408. It will be noted that the connector 406 may be a simple passage used for robot-to-robot hand off between the wafer handlers 402, or may provide additional hardware to support transfer of wafers such as a transport system (e.g., a cart, an additional robot handler, or the like) and/or stand offs or a buffer station to support a wafer in transition between the wafer handlers 402.

As depicted, on robotic handler may employ three facet splitters for connecting to six different process modules. Alternatively, as depicted on the left side of FIG. 4, a square robotic handler may use a first facet for coupling to a load lock, a second facet for coupling to another robotic handler, a third facet for a conventional (and relatively large) process module, and a fourth facet for a facet splitter, which may in turn provide a physical interface to two or more (relatively small) process modules. Thus it will be appreciated that the use of facet splitters to increase the number of ports to and from a robotic handler may be generally employed to accommodate numerous different physical layouts. Facet splitters may also advantageously permit improved usage of layout space by enabling denser configurations of irregularly shaped and sized process modules.

While the invention has been described in connection with certain preferred embodiments, numerous variations and modifications will be readily apparent to one of ordinary skill in the art, and all such variations, modifications, and the like are intended to fall within the scope of this disclosure, which is to be interpreted in the broadest sense allowable by law.

1-21. (canceled)

22. A device comprising:
a first facet, the first facet including an opening for passage of a substrate, and the first facet shaped and sized for removable and replaceable attachment in a vacuum-sealed engagement to a port of a substrate handler;
a plurality of additional facets, each one of the plurality of additional facets including an opening for passage of the substrate, and shaped and sized for removable and replaceable attachment in a vacuum-sealed engagement to a port of a process module; and
an interior interconnecting the opening of the first facet and the opening of each one of the plurality of additional facets, the interior shaped and sized for passage of the substrate from the first facet to any one of the plurality of additional facets.

23. The device of claim 22 wherein the plurality of additional facets each includes a mounting surface substantially similar to a mounting surface of the port of the substrate handler.

24. The device of claim 22 wherein the first facet includes a mounting surface substantially complementary to a mounting surface of the port of the substrate handler.

25. The device of claim 22 further comprising a process module attached to each one of the plurality of additional facets.

26. The device of claim 22 wherein the plurality of additional facets includes exactly two facets.

27. The device of claim 22 wherein a plurality of planes substantially tangent to each one of the plurality of additional facets are oriented at ninety degrees to one another.

28. The device of claim 22 wherein one or more of the vacuum-sealed engagements includes an isolation valve for selectively isolating one or more of the process modules.

29. The device of claim 22 further comprising an connector having a first end, a second end, and an interior passage, the first end of the connector attached in a vacuum-sealed engagement to one of the additional facets, the second end of the connector attached in a vacuum-sealed engagement to a process module, and the interior passage providing access to the process module by an end effector and a substrate.

30. The device of claim 22 further comprising a substrate handler attached to the first facet.

31. The device of claim 30 wherein the substrate handler has a substantially square layout including four ports on four sides thereof.

32. The device of claim 31 wherein at least one of the four ports is coupled in a vacuum-sealed engagement to a transport system that transports substrates to a remote chamber.

33. The device of claim 31 wherein at least one of the four ports is coupled in a vacuum-sealed engagement to a load lock.

34. The device of claim 31 wherein at least one of the four ports is coupled in a vacuum-sealed engagement to a second substrate handler.

35. The device of claim 22 wherein the interior includes at least one shelf for holding a wafer.

36. A device comprising:
a first facet, the first facet presenting a surface substantially similar to a mounting surface of a first process module and shaped and sized for removable and replaceable attachment in a vacuum-sealed engagement to a mounting surface of a port of a substrate handler;
a plurality of additional facets, at least one of the plurality of additional facets shaped and sized for removable and replaceable attachment in a vacuum-sealed engagement to a second process module having a second mounting surface that is non-complementary to the mounting surface of the port of the substrate handler; and
an interior interconnecting the first facet and the plurality of additional facets, the interior shaped and sized for passage of an end effector carrying a substrate from the first facet to any one of the plurality of additional facets.

37. The device of claim 36 wherein the plurality of additional facets have a substantially common mounting surface shape.

38. The device of claim 36 wherein the plurality of additional facets have two or more substantially different mounting surface shapes.

39. The device of claim 36 wherein a plurality of planes substantially tangent to each one of the plurality of additional facets are oriented at ninety degrees to one another.

40. A device comprising:
a substrate handler including four ports and a robotic handler with an end effector for moving at least one substrate among the four ports; and
a plurality of facet adapters removably and replaceably coupled in a vacuum-sealed engagement with two or more of the four ports of the substrate handler, each facet adapter shaped and sized to present one of the four ports as two or more openings for removably and replaceably coupling in a vacuum-sealed engagement with two or more process modules, and each facet adapter having an interior for passage of a substrate on an end effector of the robotic handler therethrough, whereby the four ports of the substrate handler are coupled to more than four process modules.

41. The device of claim 40 wherein at least one of the four ports is coupled in a vacuum-sealed engagement to a transport system that transports substrates to a remote chamber.

42. The device of claim 40 wherein at least one of the four ports is coupled in a vacuum-sealed engagement to a load lock.

43. The device of claim 40 wherein at least one of the four ports is coupled in a vacuum-sealed engagement to a second substrate handler.
